(19) United States
(12) Patent Application Publication
(10) Pub. No.: US 2007/0218587 A1
(43) Pub. Date: Sep. 20, 2007

(54) SOFT CONDUCTIVE POLYMER PROCESSING PAD AND METHOD FOR FABRICATING THE SAME

(75) Inventors: Yuchun Wang, Santa Clara, CA (US); Yuan A. Tian, San Jose, CA (US); Yongqi Hu, Fremont, CA (US); Rashid A. Mavliev, Campbell, CA (US); Robert A. Ewald, Aptos, CA (US)

Correspondence Address: PATTERSON & SHERIDAN, LLP, 3040 POST OAK BOULEVARD, SUITE 1500, HOUSTON, TX, 77056, US

(73) Assignee: APPLIED MATERIALS, INC.

(21) Appl. No.: 11/683,197

(22) Filed: Mar. 7, 2007

Related U.S. Application Data
(60) Provisional application No. 60/780,242, filed on Mar. 7, 2006.

(51) Int. Cl. H01L 21/00

(52) U.S. Cl. 438/107

(57) ABSTRACT

Embodiments of the invention generally provide a conductive processing pad and a method for fabricating the same. In one embodiment the conductive processing pad includes a grid of conductive material disposed in a polymer layer. A plurality of perforations is formed through the polymer in the open area defined by the grid such that the side walls of the perforations do not expose the conductive grid. In another embodiment, a method for forming a conductive pad is provided. In one embodiment, the method includes the steps of pressing a conductive grid into a polymer sheet at a temperature greater than the polymer's last transition temperature but lower than the melting point of the material comprising the conductive grid and perforating the polymer sheet through the open area defined by the grid without exposing the conductive grid.

### CROSS-REFERENCE TO RELATED APPLICATION

This application claims benefit of U.S. Provisional Application Ser. No. 60/780,242 filed Mar. 7, 2006 (Attorney Docket No. APPM/10966L), which is incorporated by reference in its entirety.

### BACKGROUND OF THE INVENTION

1. Field of the Invention

Embodiments of the present invention generally relate to planarizing or polishing a substrate. More particularly, the invention relates to a polishing pad for use in a electrochemical mechanical planarization process.

2. Description of the Related Art

In the fabrication of integrated circuits and other electronic devices on substrates, multiple layers of conductive, semiconductive and dielectric materials are deposited on or removed from a feature side, i.e., a deposit receiving surface, of a substrate. As layers of materials are sequentially deposited and removed, the feature side of the substrate may become non-planar and require planarization. Planarization is a procedure where previously deposited material is removed from the feature side of a substrate to form a generally even, planar or level surface. The process is useful in removing undesired surface topography and surface defects, such as rough surfaces, agglomerated materials, crystal lattice damage and scratches. The planarization process is also useful in forming features on a substrate by removing excess deposited material used to fill the features and to provide an even or level surface for subsequent deposition and processing.

Electrochemical Mechanical Planarization (ECMP) is one exemplary planarization process that is used to remove materials from the feature side of a substrate. An ECMP system uses a pad having conductive properties to facilitate application of an electrical bias to a surface of the substrate. An electrolyte provides a conductive path between the bias substrate surface and one or more electrodes. The substrate is held against and moved relative to the pad to promote removal of material from the substrate through a combination of abrasive and electrochemical activity.

Although ECMP processes have demonstrated robust processing results, there is an ongoing effort to develop a pad with improved polishing qualities. Since the pad is also consumed during the ECMP process, improvements in a method of manufacturing the pad, along with improvements which may reduce scratch defects to the device surface, are needed to reduce the cost of ownership along with improving to process yield.

Therefore, there is a need for an improved processing pad.

### SUMMARY OF THE INVENTION

Embodiments of the invention generally provide a conductive processing pad assembly and a method for fabricating the same. In one embodiment the conductive processing pad assembly includes a grid of conductive material disposed in a polymer layer. A plurality of perforations is formed through the polymer in the open area defined by the grid such that the side walls of the perforations do not expose the conductive grid.

In another embodiment, the polymer sheet further comprises a material having a wear rate substantially equal to a wear rate of the conductive grid when moved against a conductive surface of a substrate, such as copper or tungsten.

In another embodiment, the polymer sheet further comprises a material that is semi-soluble when exposed to at least one of a polishing and/or cleaning solution and/or water solution. The semi-soluble material allows an upper surface of the polymer sheet to wear while processing, while the underlying bulk material comprising the polymer sheet retains its structural integrity such that the integrity of the grid and polymer laminate is maintained.

In another embodiment, a method for forming a conductive pad assembly is provided. In one embodiment, the method includes the steps of pressing a conductive grid into a polymer sheet at a temperature greater than the polymer's last transition temperature but lower than the melting point of the material comprising the conductive grid and perforating the polymer sheet through the open area defined by the grid without exposing the conductive grid.

### DESCRIPTION OF THE DRAWINGS

A more particular description of the invention, briefly summarized above, may be had by reference to the embodiments thereof which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a sectional view of an electrochemical processing (ECMP) having one embodiment of a conductive processing pad assembly;

FIG. 2 is a partial sectional view of the conductive processing pad assembly of FIG. 1;

FIG. 3 is a partial sectional view of another embodiment of a conductive processing pad assembly;

FIG. 4 is a top view of one embodiment of a conductive grid;

FIG. 5 is a top view of the conductive processing pad assembly of FIG. 1;

FIG. 6 is a partial sectional view of another embodiment of a conductive processing pad assembly; and

FIGS. 7A-C depicts one embodiment of a sequence for fabricating a conductive layer of a processing pad assembly.

To facilitate understanding, identical reference numerals have been used, where possible, to designate identical elements that are common to the figures. It is contemplated that elements disclosed in one embodiment may be beneficially utilized on other embodiments without specific further recitation.

### DETAILED DESCRIPTION

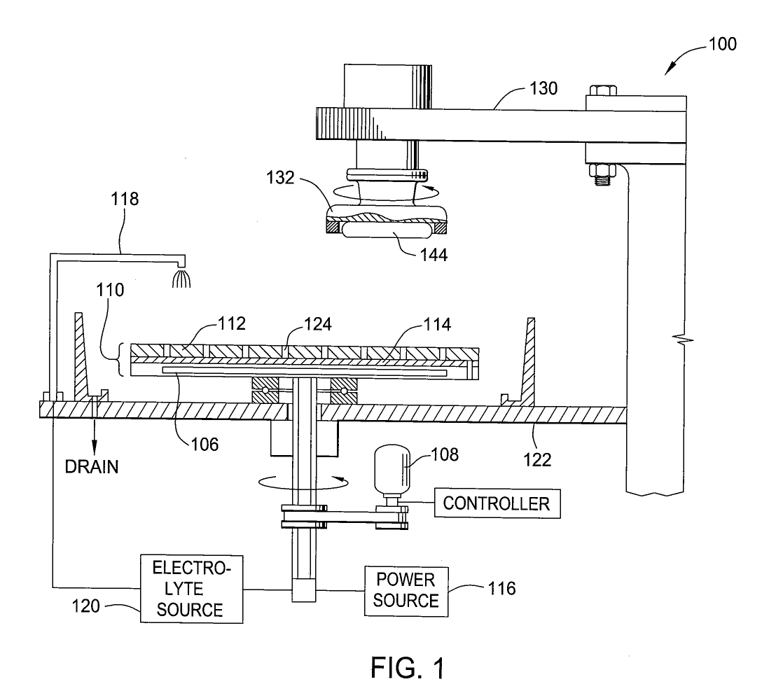

FIG. 1 depicts an ECMP system 100 having one embodiment of a conductive pad assembly of the present invention. Although the ECMP processing system 100 shown provides rotational motion between a circular conductive pad assembly 110 and a substrate 144 processed thereon, it is contemplated that the conductive pad assembly 110 may be utilized in other electroprocessing systems, including those using polishing pad assemblies in the form of webs and belts, and in systems that utilize linear, orbital, rotational or other motions between the substrate and pad assembly during processing. One system that may be adapted to benefit from the invention includes the REFLEXION® LK Ecmp system, available from Applied Materials, Inc. Another system that may be adapted to benefit from the invention is described in U.S. patent application Ser. No. 10/941,060, filed Sep. 14, 2004, which is incorporated by reference in its entirety. It is contemplated that suitably adapted systems having other configurations, and/or available from other manufacturers may be utilized.

In the embodiment depicted in FIG. 1, the ECMP system 100 includes a mechanism 130 that supports a polishing head 132 over a platen 106. The platen 106 is disposed on a base 122 of the system 100 and is coupled to a motor 108 which controllably rotates the platen 106 and pad assembly 110 disposed thereon. A polishing fluid delivery arm 118 is coupled to an electrolyte source 120 which may be positioned above the pad assembly 110 to deliver electrolyte (processing fluid) to the pad surface during processing.

The pad assembly 110 includes at least a conductive top layer 112 and an underlying electrode 114. In one embodiment, the conductive top layer 112 and the electrode 114 are coupled to form a one piece replaceable assembly. The conductive top layer 112 and the electrode 114 are coupled to a power source 116. The power source 116 is configured to apply an electrical bias to the conductive top layer 112 and electrode 114. The electrode 114 may comprise a plurality of independently-biasable segments which may be separately and independently powered by the power source 116 relative to the conductive top layer 112, as shown by segments 208A, 208B of FIG. 3. The segments 208A, 208B may have any shape or orientation, for example, concentric rings, linear, curved, concentric shapes or involute curves, among others.

The electrode 114 may be fabricated from corrosion resistant conductive material, such as metals, conductive alloys, metal coated fabrics, conductive polymers, conductive pads, and the like. Conductive metals include Sn, Ni, Cu, Au, and the like. Conductive metals also include a corrosion resistant metal such as Sn, Ni, or Au coated over an active metal such as Cu, Zn, Al, and the like. Conductive alloys include inorganic alloys and metal alloys such as bronze, brass, stainless steel, or palladium-tin alloys, among others. Metal coated fabric may be woven or non-woven with any corrosion resistant metal coating. The electrode 114 may be a foil to about 100 mils in thickness.

The conductive top layer 112 generally includes a plurality of apertures 124 formed therethrough which exposes the underlying electrode 114. During processing, electrolyte provided to the pad assembly 110 by the electrolyte source 120 flows into the apertures 124 to establish a conductive path between the electrode 114 and the surface of the substrate 144 which is biased by the conductive top layer 112.

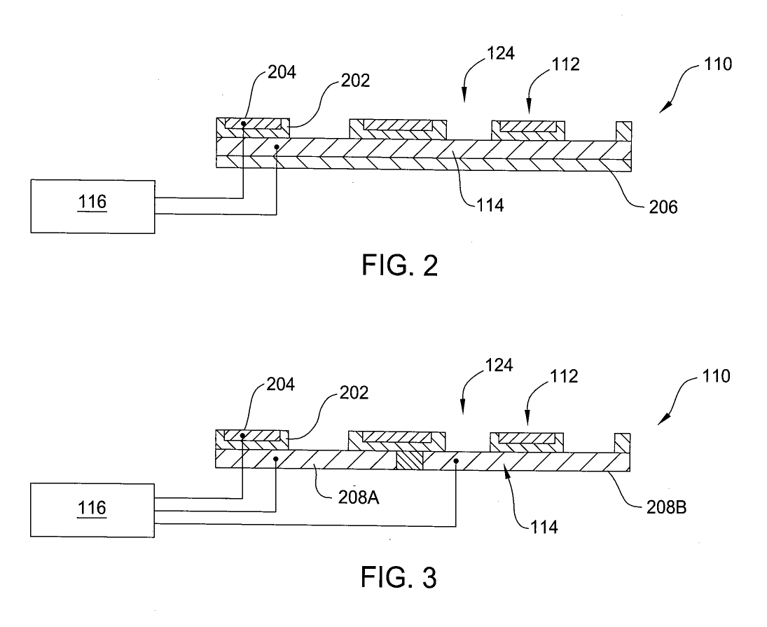

FIG. 2 is a partial sectional view of the conductive processing pad assembly 110 illustrating the conductive top layer 112 in greater detail. The conductive top layer 112 includes a polymer layer 202 and a conductive grid 204. The polymer layer 202 may be polyurethane or other suitable polymer. In one embodiment, the polymer layer 202 has a wear rate substantially equal to a wear rate of the conductive grid 204 when the layer 202 and grid 204 are moved against a surface of the substrate 144, such as a substantially copper or tungsten surface.

In one embodiment, the polymer layer 202 is fabricated from a material that is semi-soluble when exposed to the polishing fluid, water and/or conditioning fluid. The semi-soluble polymer layer 202 allows the exposed surface of the polymer layer 202 to be removed, while maintaining the structural integrity of the pad assembly 110 so that there is little or no relative movement of the conductive grid 204.

The conductive grid 204 is disposed in the polymer layer 202 such that both the conductive grid 204 and polymer layer 202 define the surface of the processing pad assembly 110 on which the substrate 114 is processed. The polymer layer 202 isolates the conductive grid 204 from the sidewalls of the apertures 124 formed through the pad assembly 110 to expose the conductive layer 114.

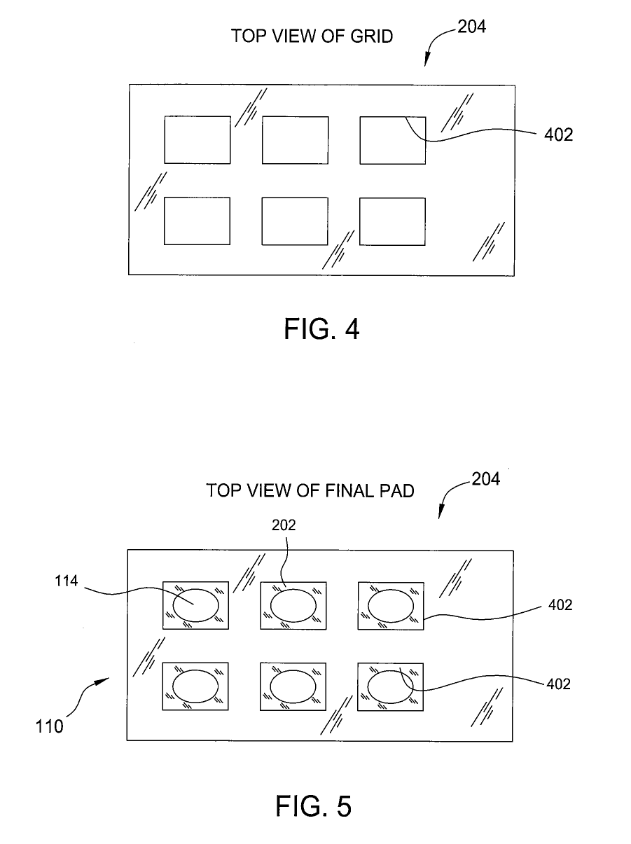

Referring additionally to FIGS. 4-5, the conductive grid 204 has a plurality of openings 402 in which the apertures 124 are defined. The openings 402 are shown as having a rectangular form, but may alternatively have circular, square, polygonal or other geometric profile. Likewise, the apertures 124, although shown as having a circular form, but alternatively may have square, rectangular, polygonal or other geometric profile.

The conductive grid 204 is generally fabricated from a conductive material, such as metal, conductive polymer or graphite, among others. In one embodiment, the conductive grid 204 comprises at least one of stainless steel, tin or nickel. The apertures 124 may be formed in the conductive grid 204 by etching, laser cutting, plasma cutting, micromachining, molding, casting, stamping, expanding, perforating or formed by other method.

Optionally, a subpad may be included in the processing pad assembly 110. The subpad may be a polymer, such as a foamed polyurethane, selected to enhance processing performance. In one embodiment, the subpad has a thickness of less than or equal to about 100 mils, hardness between about 2 to about 90 Shore A, and about 3 percent compression under a pressure of about 0.5 psi. A 100 mil thick subpad should have a compression of at least 2 percent at 0.5 psi, whereas a 200 mil thick subpad should have a compression of at least 1 percent at 0.5 psi compression modulus 50 or less at 0.1-1 psi. In one embodiment, the subpad has greater then 10 percent compression, for example 25 percent, at 1-9 psi at 0.2 in/min strain.

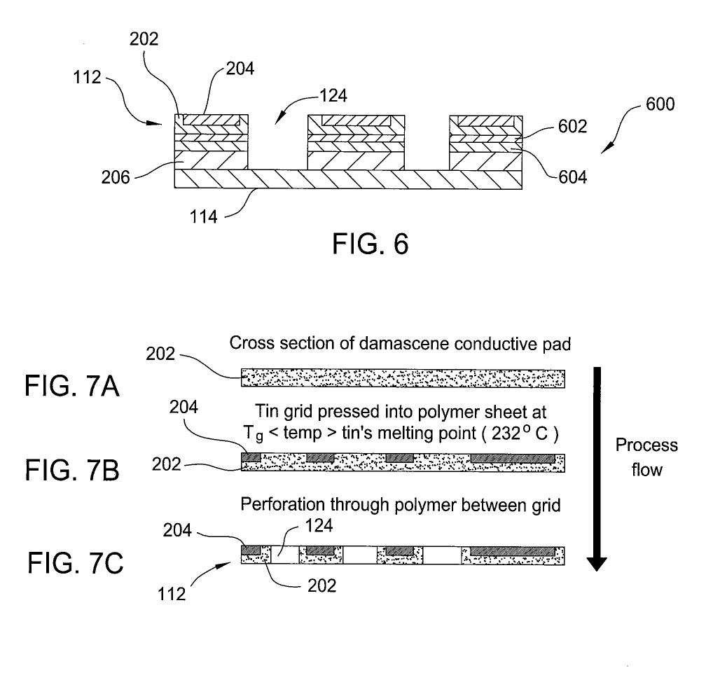

In the embodiment depicted in FIG. 3, an optional subpad 206 is disposed below the electrode 114. In the embodiment of a pad assembly 600 depicted in FIG. 6, a subpad 206 is disposed between the conductive top layer 112 and the electrode 114. The pad assembly 600 additionally includes a conductive backing 602 and interposed pad 604. The conductive backing 602 is generally a conductive layer or foil utilized to promote uniform biasing of the conductive grid 204. The interposed pad 604 is provided to add mechanical strength to the pad assembly 600. In one embodiment, the interposed pad 604 is a MYLAR sheet.

FIGS. 7A-B depict one embodiment of a method for fabricating a conductive top layer 112 of a pad assembly 110. The method begins at FIG. 7A by heating a polymer layer 202 between its glass transition temperature and the melting temperature of the conductive grid 204 (about 232 degrees Celsius for tin). At FIG. 7B, the conductive grid 204 is pressed into the polymer layer 202. At FIG. 7C, the apertures 124 are formed through the polymer layer 202 and openings 402 of the grid 204 as not to expose the walls of openings 402 through the polymer layer 202. The sequence of forming the conductive top layer 112 may be performed prior to or after coupling the conductive top layer 112 to the electrode 114.

While the foregoing is directed to the preferred embodiment of the present invention, other and further embodiments of the invention may be devised without departing from the basic scope thereof, and the scope thereof is determined by the claims that follow.

What is claimed is:

1. A conductive processing pad assembly comprising:
a polymer layer;
a grid of conductive material disposed in a polymer layer; and
a plurality of perforations formed through the polymer layer in an open area defined by the grid such that side walls of the perforations do not expose the conductive grid.

2. The conductive processing pad assembly of claim 1, wherein the polymer layer further comprises:
a material having a wear rate substantially equal to a wear rate of the conductive grid when moved against a conductive surface of a substrate.

3. The conductive processing pad assembly of claim 1, wherein the polymer layer further comprises:
a material having a wear rate substantially equal to a wear rate of the conductive grid when moved against at least one of a copper or a tungsten surface of a substrate.

4. The conductive processing pad assembly of claim 1, wherein the polymer layer further comprises:
a material that is semi-soluble when exposed to at least one of a polishing solution, cleaning solution or water solution.

5. The conductive processing pad assembly of claim 1, wherein the polymer layer further comprises:
a semi-soluble upper surface; and
a underlying non-soluble bulk material.

6. The conductive processing pad assembly of claim 1 further comprising:
a conductive electrode layer coupled to a side of the polymer layer opposite the conductive grid.

7. The conductive processing pad assembly of claim 6, wherein the conductive electrode layer further comprises:
independently biasable segments.

8. The conductive processing pad assembly of claim 6 further comprising:
a dielectric subpad sandwiched between the polymer layer and the conductive electrode layer.

9. The conductive processing pad assembly of claim 6 further comprising:
a dielectric subpad coupled to a side of the conductive electrode layer opposite the polymer layer.

10. The conductive processing pad assembly of claim 1, wherein the conductive grid is fabricated from at least one of a metal, tin, nickel, stainless steel, conductive polymer or graphite.

11. The conductive processing pad assembly of claim 1, wherein the conductive grid further comprises:
openings having a rectangular, circular or polygonal profile.

12. The conductive processing pad assembly of claim 11, wherein polymer layer extends into the openings formed in the conductive grid.

13. The conductive processing pad assembly of claim 12, wherein a portion of the polymer layer disposed in the opening of the conductive grid has at least one of the plurality of perforations extending therethrough.

14. The conductive processing pad assembly of claim 13 further comprising:
a conductive electrode layer coupled to the polymer layer and exposed through the perforations.

15. A conductive processing pad assembly comprising:
a polymer layer having a plurality of perforations formed therethrough;
a grid of conductive material disposed in a polymer layer and exposed on a top surface of the polymer layer; and
a conductive electrode layer coupled to the polymer layer and exposed from the top surface through the perforations.

16. The conductive processing pad assembly of claim 15, wherein the polymer layer further comprises:
a material having a wear rate substantially equal to a wear rate of the conductive grid when moved against at least one of a copper or a tungsten surface of a substrate.

17. The conductive processing pad assembly of claim 15, wherein the polymer layer further comprises:
a material that is semi-soluble when exposed to at least one of a polishing solution, cleaning solution or water solution.

18. The conductive processing pad assembly of claim 15, wherein the polymer layer further comprises:
a semi-soluble upper surface comprising the top surface; and
a underlying non-soluble bulk material.

19. The conductive processing pad assembly of claim 15, wherein the conductive electrode layer further comprises:
independently biasable segments.

20. A method for fabricating a conductive processing pad assembly, comprising:
pressing a conductive grid into a polymer sheet at a temperature greater than the polymer's last transition temperature but lower than the melting point of the material comprising the conductive grid; and
perforating the polymer sheet through the open area defined by the grid without exposing the conductive grid.
